(19) United States
(12) Patent Application Publication
(10) Pub. No.: US 2026/0013053 A1
(43) Pub. Date: Jan. 8, 2026

(54) DRIVE PORTION FOR DISPLAY DEVICE AND DISPLAY DEVICE INCLUDING THE SAME

(71) Applicant: Samsung Display Co., LTD., Yongin-si (KR)

(72) Inventor: SIHYUNG AN, Yongin-si (KR)

(21) Appl. No.: 19/249,097

(22) Filed: Jun. 25, 2025

(30) Foreign Application Priority Data
Jul. 5, 2024 (KR) 10-2024-0088892

(51) Int. Cl. H05K 5/00

(52) U.S. Cl. CPC H05K 5/0082; H05K 5/0069

(57) ABSTRACT

A drive portion for a display device according to an embodiment may include: a circuit board including a signal transmission line; a connection portion attached to the circuit board; and a plurality of insulation patterns located in an area where the circuit board and the connection portion are connected with each other. The plurality of insulation patterns may be located between the circuit board and connection portion and may not overlap the signal transmission line.

This application claims priority to Korean Patent Application No. 10-2024-0088892, filed on Jul. 5, 2024, and all the benefits accruing therefrom under 35 U.S.C. § 119, the content of which in its entirety is herein incorporated by reference.

### BACKGROUND

### 1. Field

The present disclosure relates to a drive portion for a display device and a display device including the drive portion.

### 2. Description of the Related Art

A display device includes a liquid crystal display (LCD), a plasma display panel (PDP), an organic light emitting diode (OLED) device, a field emission display (FED) device, and an electrophoretic display device.

The display device may include a flexible circuit portion for transmitting signals for displaying an image and a printed circuit board (PCB) connected to the flexible circuit portion.

A connection portion may be attached to the printed circuit board, and the printed circuit board may be connected to an available circuit portion through the connection portion.

In some cases, for stable operation of the display device, stable signal supply of high-speed signal wires, such as, for example, power supply lines, among a plurality of wires formed on the printed circuit board may be desired.

### SUMMARY

Embodiments described herein provide a drive portion for a display device, which can stably supply a signal from a printed circuit board (PCB), and a display device including the drive portion.

However, the tasks that embodiments seek to solve are not limited to the tasks described herein and can be expanded in various ways within the range of technical ideas included in embodiments.

A drive portion for a display device according to an embodiment may include: a circuit board including a signal transmission line; a connection portion attached to the circuit board; and a plurality of insulation patterns located in an area where the circuit board and the connection portion are connected with each other. The plurality of insulation patterns are located between the circuit board and the connection portion and do not overlap the signal transmission line.

A display device according to an embodiment may include: a display panel including a plurality of pixels; a flexible circuit film connected to the display panel; a circuit board connected to the flexible circuit film and including a signal transmission line; a connection portion attached to the circuit board and connecting the flexible circuit film and the circuit board; and a plurality of insulation patterns in an area where the circuit board and the connection portion overlap each other. The plurality of insulation patterns are located between the circuit board and the connection portion and do not overlap the signal transmission line.

An electronic device according to an embodiment may include a display module including a display device; and a processor connected to the display module and configured to control the display module to display an image. The display device may include a display panel including a plurality of pixels; a flexible circuit film connected to the display panel; a circuit board connected to the flexible circuit film and including a signal transmission line; a connection portion attached to the circuit board and connecting the flexible circuit film and the circuit board; and a plurality of insulation patterns in an area where the circuit board and the connection portion overlap each other. The plurality of insulation patterns are located between the circuit board and the connection portion and do not overlap the signal transmission line.

An insulation resistance value of each of the plurality of insulation patterns may range from about 1.00×10¹³(Ω) to about 2.00×10¹³(Ω).

An insulation resistance value of each of the plurality of insulation patterns may range from about 1.30×10¹³(Ω) to about 1.60×10¹³(Ω).

Each of the plurality of insulation patterns may include silk.

The connection portion may overlap the signal transmission line, and the plurality of insulation patterns may be located at a side of the signal transmission line.

The signal transmission line may be a power transmission line.

The connection portion may include a plurality of connection pins and a connection plate, one or more of the plurality of connection pins may be connected with the signal transmission line, the connection plate may be connected with the circuit board through an expansion portion of opposite ends of the connection plate, and the connection plate may overlap the signal transmission line and the plurality of insulation patterns.

The plurality of insulation patterns may include a first insulation pattern overlapping the expansion portion of the connection plate and a second insulation pattern located at the side of the signal transmission line.

A portion of the first insulation pattern may extend along an edge of the connection plate.

The first insulation pattern may include a plurality of sub-insulation patterns arranged in a row and spaced apart from each other along a direction in which the connection plate extends.

The first insulation pattern may include a plurality of sub-insulation patterns arranged in a row while being spaced apart from each other along an extension direction in which the connection plate extends, and the plurality of sub-insulation patterns may be arranged such that each of the plurality of sub-insulation patterns is diagonal with respect to with the direction in which the connection plate extends.

According to the embodiments, a drive portion for a display device, which can stably supply a signal from a printed circuit board (PCB), and a display device including the drive portion can be provided.

However, it is clear that the effects of embodiments are not limited to the effects described herein, and can be expanded in various ways within a range that does not deviate from the idea and region of the present disclosure.

### BRIEF DESCRIPTION OF THE DRAWINGS

FIG. 1 is a top plan view of a display device according to an embodiment.

FIG. 2 is a cross-sectional view of FIG. 1, taken along the line I-I′.

FIG. 3 is a top plan view of a display device according to another embodiment.

FIG. 4 is a cross-sectional view of FIG. 3, taken along the line II-II′.

FIG. 5 and FIG. 6 are top plan views of a part of a drive area of the display device according to an embodiment.

FIG. 7 is a cross-sectional view of a part of FIG. 5.

FIG. 8 and FIG. 9 are top plan views of a part of a drive area of the display device according to an embodiment.

FIG. 10 and FIG. 11 are top plan views of a part of a drive area of the display device according to an embodiment.

FIG. 12 and FIG. 13 are top plan views of a part of a drive area of the display device according to an embodiment.

FIG. 14 and FIG. 15 are top plan views of a part of a drive area of the display device according to an embodiment.

FIG. 16 and FIG. 17 are graphs that show a result of an experimental example.

FIG. 18 is a block diagram of an electronic device according to an embodiment.

FIGS. 19 to 21 are schematic views of electronic devices according to various embodiments.

### DETAILED DESCRIPTION

Hereinafter, with reference to the accompanying drawing, various embodiments of the present disclosure are described in detail and thus a person of ordinary skill in the art to which the present disclosure belongs can easily practice this disclosure. The present disclosure may be implemented in many different forms and is not limited to the embodiments described herein.

In order to clearly describe the present disclosure, parts irrelevant to the description have been omitted, and like reference numerals designate like elements throughout the specification.

The accompanying drawings are for easy understanding of the embodiments disclosed in this specification, and the technical idea disclosed in this specification is not limited by the accompanying drawing, and it should be understood that all changes, equivalents, or substitutes included in the spirit and scope of the present disclosure are included.

In the drawings, size and thickness of each element are arbitrarily illustrated for convenience of description, and the present disclosure is not necessarily limited to as illustrated in the drawing. In the drawings, the thickness of layers, films, panels, regions, and the like are exaggerated for clarity. In the drawings, the thickness of some layers and regions is exaggerated for better understanding and ease of description.

It will be understood that when an element such as, for example, a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to mean positioned above or below the target element, and will not necessarily be understood to mean positioned “at an upper side” based on an opposite to gravity direction.

Unless explicitly described to the contrary, the word “comprise”, and variations such as, for example, “comprises,” “comprising”, “includes,” or “including,” will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

Throughout the specification, the term “connected” is not limited to when two or more constituent elements are directly connected, but also includes when two or more constituent elements are indirectly connected through another constituent element, or when physically connected or electrically connected, and the term may include a case in which substantially integral parts are connected to each other although they are referred to by different names according to positions or functions.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

Spatially relative terms, such as, for example, “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Hereinafter, various embodiments and variations will be described in detail with reference to the accompanying drawings.

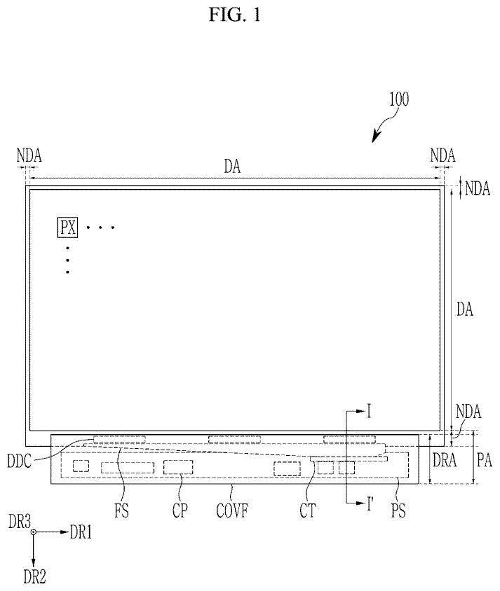

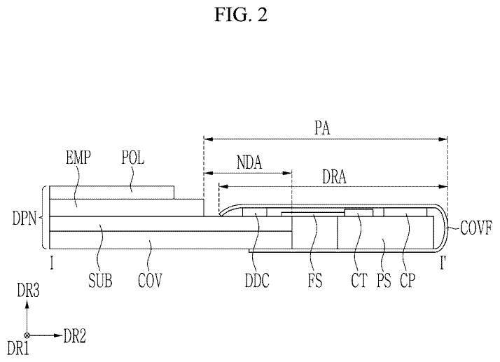

Referring to FIG. 1 and FIG. 2, a display device 100 according to an embodiment will be described. FIG. 1 is a top plan view of a display device according to an embodiment, and FIG. 2 is a cross-sectional view of FIG. 1, taken along the line I-I′.

Referring to FIG. 1 and FIG. 2, the display device 100 according to the present embodiment may include a display panel DPN that includes a display area DA including a plurality of pixels PX and displaying an image, and a non-display area NDA surrounding the display area DA along a first direction DR1 and a second direction DR2.

A drive area DRA may be in the periphery of a portion of the non-display area NDA of the display panel DPN, and the drive area DRA includes a plurality of driving chips DDC, a flexible circuit film FS connected to the display panel DPN, and a circuit board PS physically and electrically connected to the flexible circuit film FS through a connection portion CT. A peripheral area PA may include the drive area DRA and the portion of the non-display area NDA of the display panel DPN adjacent to the drive area DRA.

The drive area DRA and the peripheral area PA may be located below the non-display area NDA of the display panel DPN along the second direction DR2, but embodiments of the present disclosure are not limited thereto.

The plurality of driving chips DDC may be located in the portion of the non-display area NDA of the display panel DPN of the peripheral area PA. For example, the plurality of driving chips DDC may include a display driver IC chip, a timing controller (T-CON), a graphic random access memory (GRAM), and a power generating circuits.

The plurality of driving chips DDC may be connected to the circuit board PS through the flexible circuit film FS to transmit/receive a driving signal.

The plurality of driving chips DDC may be directly located on a substrate SUB, and the plurality of driving chips DDC may be connected to the substrate SUB through a film substrate.

The display panel DPN may include a substrate SUB, a plurality of light emission portions EMP located on the substrate SUB, a polarization portion POL on the plurality of light emission portions EMP of the substrate SUB, and a protection portion COV under the substrate SUB.

A plurality of electronic components CP may be located on the circuit board PS.

The circuit board PS may be connected with the flexible circuit film FS through the connection portion CT.

An insulation pattern ISP may be located between the circuit board PS and the connection portion CT. The insulation pattern ISP will be described more specifically later. The insulation pattern ISP may be located on the circuit board PS, and may be located at the periphery (side) of a signal transmission line included in the circuit board PS. The insulation pattern ISP may increase a gap between the circuit board PS and the connection portion CT and reduce unnecessary or undesired coupling between the signal transmission line of the circuit board PS and the connection portion CT.

The insulation pattern ISP may have an insulation resistance value ranging from about 1.00×10¹³ (Ω) to about 2.00×10¹³ (Ω). More specifically, the insulation pattern ISP may have an insulation resistance value ranging from about 1.30×10¹³ (Ω) to about 1.60×10¹³ (Ω). The insulation pattern ISP may include silk, but embodiments of the present disclosure are not limited thereto.

A cover film COVF may be located in the peripheral area PA. The cover film COVF may surround the plurality of driving chips DDC, the flexible circuit film FS, and the circuit board PS from the front to the back of the display panel DPN.

The cover film COVF may protect and fix the plurality of driving chips DDC, the flexible circuit film FS, and the circuit board PS of the drive area DRA, shield radio frequency (RF) noise between the drive area DRA and the outside, and provide a path for movement of static electricity and the like by connecting a ground wiring of the circuit board PS and a ground wiring of the display panel DPN.

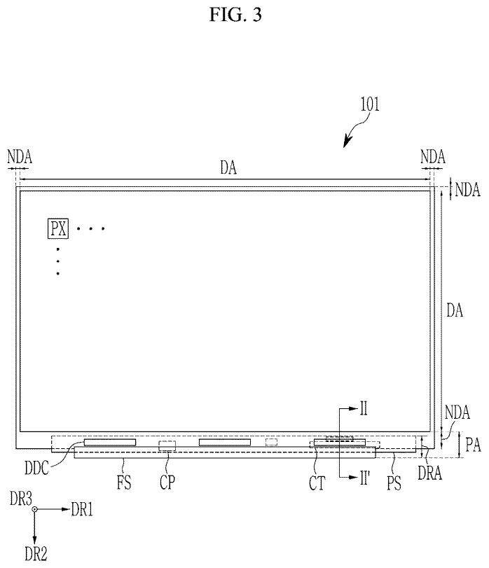

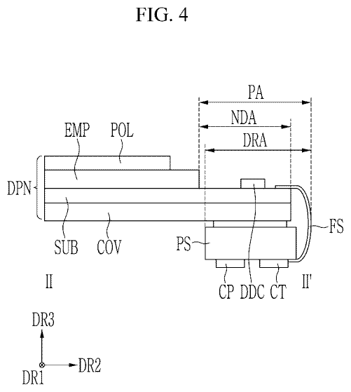

Referring to FIG. 3 and FIG. 4, a display device 101 according to another embodiment will be described. FIG. 3 is a top plan view of a display device according to another embodiment, and FIG. 4 is a cross-sectional view of FIG. 3, taken along the line II-II′.

Referring to FIG. 3 and FIG. 4, a display device 101 according to the present embodiment is similar to the display device 100 according to the embodiment described with reference to FIG. 1 and FIG. 2. Specific descriptions of the same components are omitted.

Referring to FIG. 3 and FIG. 4, the display device 101 according to the present embodiment may include a display panel DPN that includes a display area DA including a plurality of pixels PX displaying an image, a non-display area NDA surrounding the display area DA.

A drive area DRA located in the periphery of a portion of the non-display area NDA of the display panel DPN may include a plurality of driving chips DDC, a flexible circuit film FS connected to the display panel DPN, and a circuit board PS physically and electrically connected to the flexible circuit film FS through a connection portion CT. A peripheral area PA may include the drive area DRA and the portion of the non-display area NDA of the display panel DPN adjacent to the drive area DRA.

The plurality of driving chips DDC may be located in the portion of the non-display area NDA of the peripheral area PA. The plurality of driving chips DDC may be connected to the circuit board PS through the flexible circuit film FS to transmit/receive driving signals.

The flexible circuit film FS may be connected to the substrate SUB, and may be bent from a portion connected to the substrate SUB to the back surface of the display panel DPN such that a portion of the flexible circuit film FS can be located on a rear surface of the display panel DPN.

The flexible circuit film FS is bent such that a portion of the flexible circuit film FS is on the rear surface of the display panel DPN, and the portion of the bent flexible circuit film FS is connected with the circuit board PS through the connection portion CT. Accordingly, a width of the peripheral area PA arranged along the second direction DR2 can be reduced compared to a case where the flexible circuit film FS is not bent and the display panel DPN, the flexible circuit film FS, and the circuit board PS are aligned along the second direction DR2,

The portion of the flexible circuit film FS located on the rear surface of the display panel DPN may be electrically connected to the circuit board PS through the connection portion CT attached to the circuit board PS,

The insulation pattern ISP may be located between the circuit board PS and the connection portion CT. The insulation pattern ISP may be located on the circuit board PS, and may be located at the periphery of a signal transmission line included in the circuit board PS. The insulation pattern ISP may increase a gap between the circuit board PS and the connection portion CT and reduce unnecessary or undesired coupling between the signal transmission line of the circuit board PS and the connection portion CT.

The insulation pattern ISP may have an insulation resistance value of about 1.00×10¹³ (Ω) to about 2.00×10¹³ (Ω). More specifically, the insulation pattern ISP may have an insulation resistance value of about 1.30×10¹³ (Ω) to about 1.60×10¹³ (Ω). The insulation pattern ISP may include silk, but embodiments of the present disclosure are not limited thereto.

The display panel DPN may include a substrate SUB, a plurality of light emission portions EMP located on the substrate SUB, a polarization portion POL located on the plurality of light emission portions EMP of the substrate SUB, and a protection portion COV located under the substrate SUB.

A plurality of electronic components CP may be located on the circuit board PS.

Many of the features of the display device 100 according to the embodiment described herein are all applicable to the present embodiment.

In the display devices 100 and 101 according to the embodiments described herein, the width of the display panel DPN parallel to the first direction DR1 is illustrated as being wider than the width parallel to the second direction DR2, but embodiments of the present disclosure are not limited thereto. In some aspects, in the display devices 100 and 101 according to the embodiments described herein, the circuit board PS is illustrated as being located below the display panel DPN along the second direction DR2, but embodiments of the present disclosure are not limited thereto. In some aspects, in the display devices 100 and 101 according to the embodiments described herein, the flexible circuit film FS and the circuit board PS are illustrated as one, respectively, but embodiments of the present disclosure are not limited thereto. In some aspects, the number of the connection portion CT and the number of electronic components CP illustrated in the display devices 100 and 101 according to the embodiment described herein are an example, and embodiments of the present disclosure are not limited thereto.

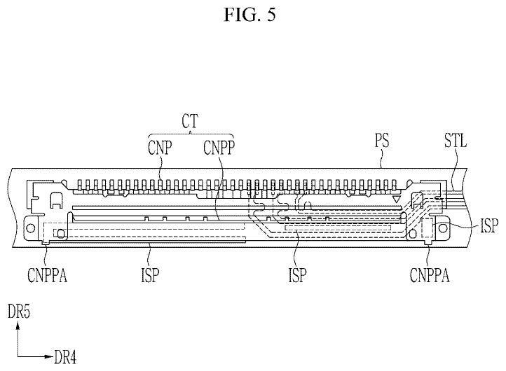

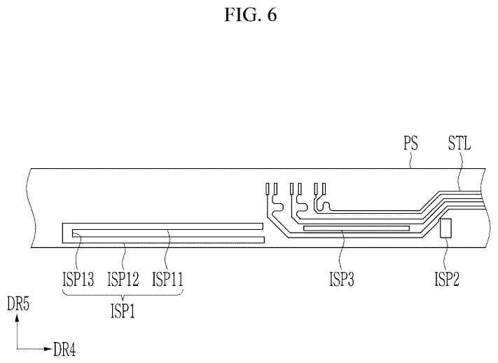

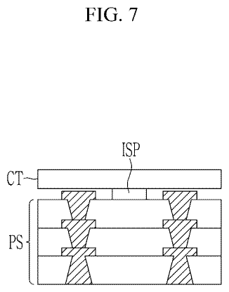

Referring to FIG. 5 to FIG. 7, the circuit board PS, the connection portion CT, and the insulation pattern ISP of the display device according to the embodiment will be described in more detail. FIG. 5 and FIG. 6 are top plan views of a part of a drive area of the display device according to an embodiment, and FIG. 7 is a cross-sectional view of a part of FIG. 5. FIG. 5 illustrates a part of the circuit board PS, the connection portion CT connected to the circuit board PS, and the insulation pattern ISP, and FIG. 6 illustrates a part of the circuit board PS and the insulation pattern ISP, excluding the connection portion CT in FIG. 5.

Referring to FIG. 5 and FIG. 6, the circuit board PS may include a plurality of signal transmission lines STL. The plurality of signal transmission lines STL may be high-speed signal wires, such as, for example, a power supply wire.

The connection portion CT may include a plurality of connection pins CNP connected to pads of signal lines of the circuit board PS, and a connection plate CNPP for connection with the circuit board PS.

Portions of the plurality of connection pins CNP of the connection portion CT may be connected with the plurality of signal transmission lines STL of the circuit board PS and portions of the pads included in the flexible circuit film FS connected to the display panel DPN may be connected with the portions of the plurality of connection pins CNP. Accordingly, display panel DPN may be electrically connected with the plurality of signal transmission lines STL of the circuit board PS. An electric signal applied to the plurality of signal transmission lines STL of the display panel DPN can be transmitted to the display panel DPN.

The connection plate CNPP of the connection portion CT may be attached to the circuit board PS by inserting a connecting member such as, for example, a screw into expansion portions CNPPA at opposite ends of the connection plate CNPP in a fourth direction DR4. The connection plate CNPP of the connection portion CT may include a metal.

Referring to FIG. 5 to FIG. 7, a plurality of insulation patterns ISP may be located between the circuit board PS and the connection portion CT. The plurality of insulation patterns ISP may be located on the circuit board PS, and the plurality of insulation patterns ISP may be located at the periphery of the plurality of signal transmission lines STL of the circuit board PS. The plurality of insulation patterns ISP may widen a gap between the circuit board PS and the connection portion CT and reduce the occurrence of unnecessary or undesired coupling between the plurality of signal transmission lines STL of the circuit board PS and the connection portion CT.

The plurality of insulation patterns ISP may have an insulation resistance value of about 1.00×10¹³ (Ω) to about 2.00×10¹³ (Ω). More specifically, the insulation pattern ISP may have an insulation resistance value of about 1.30×10¹³ (Ω) to about 1.60×10¹³ (Ω). The plurality of insulation patterns ISP may include silk, but embodiments of the present disclosure are not limited thereto.

The plurality of insulation patterns ISP may include a first insulation pattern ISP1 and a second insulation pattern ISP2 overlapping the expansion portions CNPPA at opposite ends of the connection plate CNPP, and a third insulation pattern ISP3 overlapping an area between the plurality of signal transmission lines STL.

The first insulation pattern ISP1 may be substantially parallel to an edge of the connection plate CNPP. More specifically, the first insulation pattern ISP1 may include a first portion ISP11 and a second portion ISP12 extending parallel to two opposing edges of the connection plate CNPP along the fourth direction DR4, and a third portion ISP13 connecting the first portion ISP11 and the second portion ISP12 to each other along a fifth direction DR5 and overlapping one of the expansion portions CNPPA of the connection plate CNPP.

The first portion ISP11 and the second portion ISP12 of the first insulation pattern ISP1 may overlap some area of the circuit board PS, in which the plurality of signal transmission lines STL are not located.

The second insulation pattern ISP2 may have a substantially quadrangle planar shape, and the third insulation pattern ISP3 may have a rectangular planar shape extending in a direction parallel to the plurality of signal transmission lines STL, but embodiments of the present disclosure are not limited thereto.

The connection plate CNPP of the connection portion CT may include a metal, and the connection plate CNPP of the connection portion CT may overlap the plurality of signal transmission lines STL of the circuit board PS, and may be coupled with the plurality of signal transmission lines STL.

Electrical resistance may occur in electric signals applied to the plurality of signal transmission lines STL due to unnecessary or undesired coupling between the plurality of signal transmission lines STL of the circuit board PS and the connection plate CNPP of the connection portion CT, and accordingly the electric signals applied to the plurality of signal transmission lines STL may be prevented from being supplied stably.

However, according to the embodiment, the plurality of insulation patterns ISP located between the circuit board PS and the connection portion CT and having a relatively large insulation resistance value may widen a gap between the circuit board PS and the connection portion CT and reduce unnecessary or undesired coupling between the signal transmission lines STL of the circuit board PS and the connection portion CT. Therefore, an electric signal can be stably supplied from the circuit board PS to the display panel DPN.

Many of the features of the display devices 100 and 101 according to the embodiments described herein are all applicable to the present embodiment.

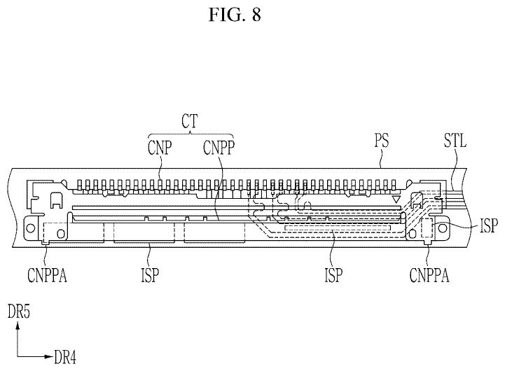

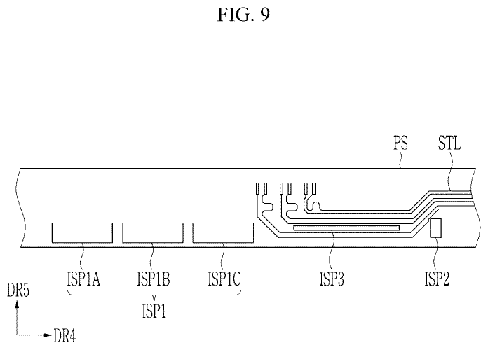

Referring to FIG. 8 and FIG. 9, the circuit board PS, the connection portion CT, and the insulation pattern ISP of the display device according to the embodiment will be described in more detail. FIG. 8 and FIG. 9 are top plan views of a part of a drive area of the display device according to an embodiment. FIG. 8 illustrates a part of the circuit board PS, the connection portion CT connected to the circuit board PS, and the insulation pattern ISP, and FIG. 9 illustrates a part of the circuit board PS and the insulation pattern ISP, excluding the connection portion CT in FIG. 8.

Referring to FIG. 8 and FIG. 9, the circuit board PS, the connection portion CT, and the plurality of insulation patterns ISP according to the present embodiment are similar to the circuit board PS, connection portion CT, and the plurality of insulation patterns ISP according to the embodiment described with reference to FIG. 5 to FIG. 7. Detailed descriptions of the same components are omitted.

The circuit board PS may include a plurality of signal transmission lines STL, and the connection portion CT may include a plurality of connection pins CNP and a connection plate CNPP.

The connection plate CNPP of the connection portion CT may be attached to the circuit board PS by inserting a connecting member such as, for example, a screw into an expansion portion CNPPA at opposite ends of the connection plate CNPP.

A plurality of insulation patterns ISP may be located between the circuit board PS and the connection portion CT. The plurality of insulation patterns ISP may be located on the circuit board PS, and the plurality of insulation patterns ISP may be located at the periphery of the plurality of signal transmission lines STL of the circuit board PS.

The plurality of insulation patterns ISP may have an insulation resistance value of about 1.00×10¹³ (Ω) to about 2.00×10¹³ (Ω). More specifically, the insulation pattern ISP may have an insulation resistance value of about 1.30×10¹³ (Ω) to about 1.60×10¹³ (Ω). The plurality of insulation patterns ISP may include silk, but embodiments of the present disclosure are not limited thereto.

The plurality of insulation patterns ISP may include a first insulation pattern ISP1 and a second insulation pattern ISP2 overlapping the expansion portions CNPPA at opposite ends, and a third insulation pattern ISP3 overlapping an area between the plurality of signal transmission lines STL.

The shapes of plurality of insulation patterns ISP according to the embodiment described with reference to FIG. 5 to FIG. 7 may be different from the shapes of the plurality of insulation patterns ISP according to the embodiment described with reference to the present embodiment.

More specifically, the first insulation pattern ISP1 may include a plurality of sub-patterns ISP1A, ISP1B, and ISP1C (also referred to herein as sub-insulation patterns) that are separated from each other. The plurality of sub-patterns ISP1A, IS{1B, and ISP1C may be arranged in parallel and spaced apart from each other along a fourth direction DR4 in which the connection plate CNPP extends. The plurality of sub-patterns ISP1A, ISP1B, and ISP1C have planar rectangular shapes, and sides of each of the plurality of sub-patterns ISP1A, ISP1B, and ISP1C, which is parallel to the fourth direction DR4 in which the connection plate CNPP extends have a relatively larger length. A width of each of the plurality of sub-patterns ISP1A, ISP1B, and ISP1C may be wider than a gap between the plurality of sub-patterns ISP1A, ISP1B, and ISP1C along the fourth direction DR4.

The second insulation pattern ISP2 may have a substantially planar quadrangular shape, and the third insulation pattern ISP3 may have a planar rectangular shape extending in a direction parallel to the plurality of signal transmission lines STL, but embodiments of the present disclosure are not limited thereto.

According to the embodiment, the plurality of insulation patterns ISP located between the circuit board PS and the connection portion CT may widen a gap between the circuit board PS and the connection portion CT and reduce unnecessary or undesired coupling between the signal transmission lines STL of the circuit board PS and the connection portion CT. Accordingly, an electric signal can be stably supplied from the circuit board PS to the display panel DPN.

Many of the features of the display devices 100 and 101 according to the embodiments described herein are all applicable to the present embodiment.

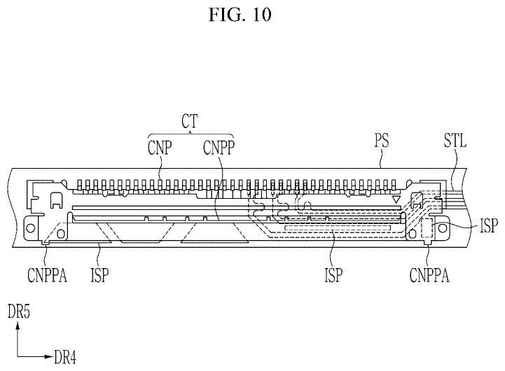

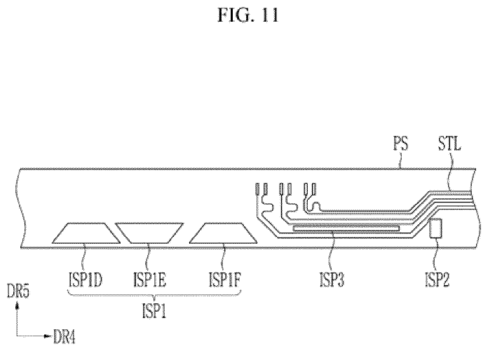

Referring to FIG. 10 and FIG. 11, the circuit board PS, the connection portion CT, and the insulation pattern ISP of the display device according to the embodiment will be described in more detail. FIG. 10 and FIG. 11 are top plan views of a part of a drive area of the display device according to an embodiment. FIG. 10 illustrates a part of the circuit board PS, the connection portion CT connected to the circuit board PS, and the insulation pattern ISP, and FIG. 11 illustrates a part of the circuit board PS and the insulation pattern ISP, excluding the connection portion CT in FIG. 10.

Referring to FIG. 10 and FIG. 11, the circuit board PS, the connection portion CT, and the plurality of insulation patterns ISP according to the present embodiment are similar to the circuit board PS, connection portion CT, and the plurality of insulation patterns ISP according to the embodiments described with reference to FIG. 5 to FIG. 9. Detailed descriptions of the same components are omitted.

The circuit board PS may include a plurality of signal transmission lines STL, and the connection portion CT may include a plurality of connection pins CNP and a connection plate CNPP.

The connection plate CNPP of the connection portion CT may be attached to the circuit board PS by inserting a connecting member such as, for example, a screw into an expansion portion CNPPA at opposite ends of the connection plate CNPP.

A plurality of insulation patterns ISP may be located between the circuit board PS and the connection portion CT. The plurality of insulation patterns ISP may be located on the circuit board PS, and the plurality of insulation patterns ISP may be located at the periphery of the plurality of signal transmission lines STL of the circuit board PS.

The plurality of insulation patterns ISP may have an insulation resistance value ranging from about 1.00×10¹³ (Ω) to about 2.00×10¹³ (Ω). More specifically, the insulation pattern ISP may have an insulation resistance value ranging from about 1.30×10¹³ (Ω) to about 1.60×10¹³ (Ω). The plurality of insulation patterns ISP may include silk, but embodiments of the present disclosure are not limited thereto.

The plurality of insulation patterns ISP may include a first insulation pattern ISP1 and a second insulation pattern ISP2 overlapping the expansion portions CNPPA at opposite ends, and a third insulation pattern ISP3 overlapping an area between the plurality of signal transmission lines STL.

The first insulation pattern ISP1 according to the present embodiment may include a plurality of sub-patterns ISP1D, ISP1E, and ISP1F that are separated from each other. The plurality of sub-patterns ISP1D, ISP1E, and ISP1F may be arranged in parallel and spaced apart from each other along a fourth direction DR4 in which the connection plate CNPP extends. The plurality of sub-patterns ISP1D, ISP1E, and ISP1F may each have a planar shape of a trapezoid having two sides parallel to the fourth direction DR4 in which the connection plate CNPP extends, and two adjacent trapezoids may have two sides inclined in opposite directions adjacent to each other. A width of each of the plurality of sub-patterns ISP1D, ISP1E, and ISP1F may be wider than a gap between the plurality of sub-patterns ISP1D, ISP1E, and ISP1F along the fourth direction DR4.

The second insulation pattern ISP2 may have a substantially planar quadrangular shape, and the third insulation pattern ISP3 may have a planar rectangular shape extending in a direction parallel to the plurality of signal transmission lines STL, but embodiments of the present disclosure are not limited thereto.

According to the embodiment, the plurality of insulation patterns ISP located between the circuit board PS and the connection portion CT may widen a gap between the circuit board PS and the connection portion CT and reduce unnecessary or undesired coupling between the signal transmission lines STL of the circuit board PS and the connection portion CT. Accordingly, an electric signal can be stably supplied from the circuit board PS to the display panel DPN.

Many of the features of the display devices 100 and 101 according to the embodiments described herein are all applicable to the present embodiment.

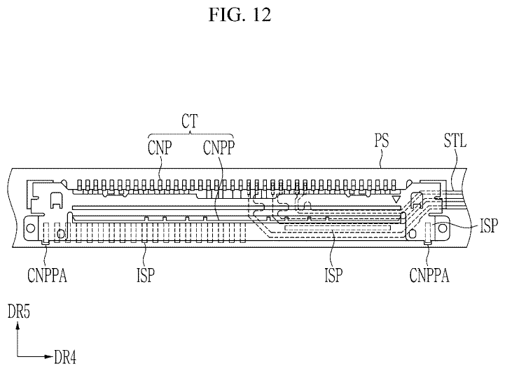

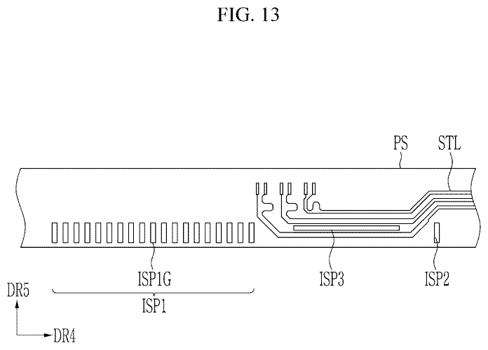

Referring to FIG. 12 and FIG. 13, the circuit board PS, the connection portion CT, and the insulation pattern ISP of the display device according to the embodiment will be described in more detail. FIG. 12 and FIG. 13 are top plan views of a part of a drive area of the display device according to an embodiment. FIG. 12 illustrates a part of the circuit board PS, the connection portion CT connected to the circuit board PS, and the insulation pattern ISP, and FIG. 13 illustrates a part of the circuit board PS and the insulation pattern ISP, excluding the connection portion CT in FIG. 12.

Referring to FIG. 12 and FIG. 13, the circuit board PS, the connection portion CT, and the plurality of insulation patterns ISP according to the present embodiment are similar to the circuit board PS, connection portion CT, and the plurality of insulation patterns ISP according to the embodiments described with reference to FIG. 5 to FIG. 11. Detailed descriptions of the same components are omitted.

The circuit board PS may include a plurality of signal transmission lines STL, and the connection portion CT may include a plurality of connection pins CNP and a connection plate CNPP.

The connection plate CNPP of the connection portion CT may be attached to the circuit board PS by inserting a connecting member such as, for example, a screw into an expansion portion CNPPA at opposite ends of the connection plate CNPP.

A plurality of insulation patterns ISP may be located between the circuit board PS and the connection portion CT. The plurality of insulation patterns ISP may be located on the circuit board PS, and the plurality of insulation patterns ISP may be located at the periphery of the plurality of signal transmission lines STL of the circuit board PS. The plurality of insulation patterns ISP may have an insulation resistance value ranging from about 1.00×10¹³ (Ω) to about 2.00×10¹³ (Ω). More specifically, the insulation pattern ISP may have an insulation resistance value ranging from about 1.30×10¹³ (Ω) to about 1.60×10¹³ (Ω). The plurality of insulation patterns ISP may include silk, but embodiments of the present disclosure are not limited thereto.

The plurality of insulation patterns ISP may include a first insulation pattern ISP1 and a second insulation pattern ISP2 overlapping the expansion portions CNPPA at opposite ends, and a third insulation pattern ISP3 overlapping an area between the plurality of signal transmission lines STL.

The first insulation pattern ISP1 according to the present embodiment may include a plurality of sub-patterns ISP1G that are separated from each other along a fourth direction DR4. The plurality of sub-patterns ISP1G may be arranged in parallel and spaced apart from each other along the fourth direction DR4 in which the connection plate CNPP extends. Each of the plurality of sub-patterns ISP1G may have a planar rectangular shape, and a gap between the plurality of sub-patterns ISP1G may be approximately the same as or wider than a width of the plurality of sub-patterns ISP1G.

The second insulation pattern ISP2 may have a substantially planar quadrangular shape, and the third insulation pattern ISP3 may have a planar rectangular shape extending in a direction parallel to the plurality of signal transmission lines STL, but embodiments of the present disclosure are not limited thereto.

According to the embodiment, the plurality of insulation patterns ISP located between the circuit board PS and the connection portion CT may widen a gap between the circuit board PS and the connection portion CT and reduce unnecessary or undesired coupling between the signal transmission lines STL of the circuit board PS and the connection portion CT. Accordingly, an electric signal can be stably supplied from the circuit board PS to the display panel DPN.

Many of the features of the display devices 100 and 101 according to the embodiments described herein are all applicable to the present embodiment.

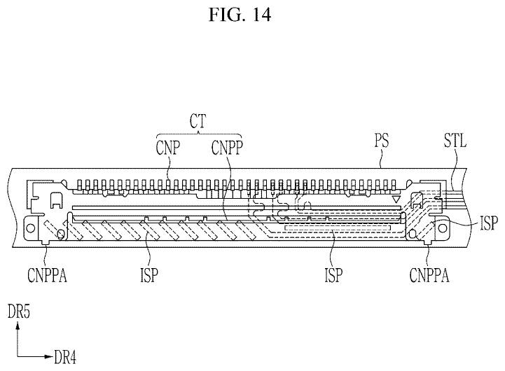

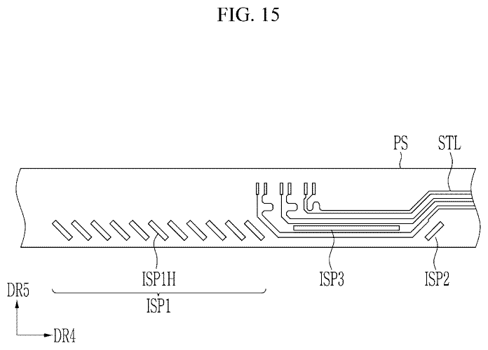

Referring to FIG. 14 and FIG. 15, the circuit board PS, the connection portion CT, and the insulation pattern ISP of the display device according to the embodiment will be described in more detail. FIG. 14 and FIG. 15 are top plan views of a part of a drive area of the display device according to an embodiment. FIG. 14 illustrates a part of the circuit board PS, the connection portion CT connected to the circuit board PS, and the insulation pattern ISP, and FIG. 15 illustrates a part of the circuit board PS and the insulation pattern ISP, excluding the connection portion CT in FIG. 14.

Referring to FIG. 14 and FIG. 15, the circuit board PS, the connection portion CT, and the plurality of insulation patterns ISP according to the present embodiment are similar to the circuit board PS, connection portion CT, and the plurality of insulation patterns ISP according to the embodiments described with reference to FIG. 5 to FIG. 13. Detailed descriptions of the same components are omitted.

The circuit board PS may include a plurality of signal transmission lines STL, and the connection portion CT may include a plurality of connection pins CNP and a connection plate CNPP.

The connection plate CNPP of the connection portion CT may be attached to the circuit board PS by inserting a connecting member such as, for example, a screw into an expansion portion CNPPA at opposite ends of the connection plate CNPP.

A plurality of insulation patterns ISP may be located between the circuit board PS and the connection portion CT. The plurality of insulation patterns ISP may be located on the circuit board PS, and the plurality of insulation patterns ISP may be located at the periphery of the plurality of signal transmission lines STL of the circuit board PS.

The plurality of insulation patterns ISP may The plurality of insulation patterns ISP may include a first insulation pattern ISP1 and a second insulation pattern ISP2 overlapping the expansion portions CNPPA at opposite ends, and a third insulation pattern ISP3 overlapping an area between the plurality of signal transmission lines STL.

The first insulation pattern ISP1 according to the present embodiment may include a plurality of sub-patterns ISP1H that are separated from each other along a fourth direction DR4. The plurality of sub-patterns ISP1H may be arranged in parallel and spaced apart from each other along the fourth direction DR4 in which the connection plate CNPP extends. Each of the plurality of sub-patterns ISP1H may have a planar parallelogram shape having two sides parallel to the fourth direction DR4 in which the connection plate CNPP extends and two sides diagonal with respect to the fourth direction DR4 in which the connection plate CNPP extends. A gap between the plurality of sub-patterns ISP1G may be approximately equal to or wider than a width of the plurality of sub-patterns ISP1G.

The second insulation pattern ISP2 may have a substantially quadrangle planar shape, and the third insulation pattern ISP3 may have a rectangular planar shape extending in a direction parallel to the plurality of signal transmission lines STL, but embodiments of the present disclosure are not limited thereto.

According to the embodiment, the plurality of insulation patterns ISP located between the circuit board PS and the connection portion CT may widen the gap between the circuit board PS and the connection portion CT and reduce unnecessary or undesired coupling between the signal transmission lines STL of the circuit board PS and the connection portion CT. Therefore, an electric signal can be stably supplied from the circuit board PS to the display panel DPN.

Many of the features of the display devices 100 and 101 according to the embodiments described herein are all applicable to the present embodiment.

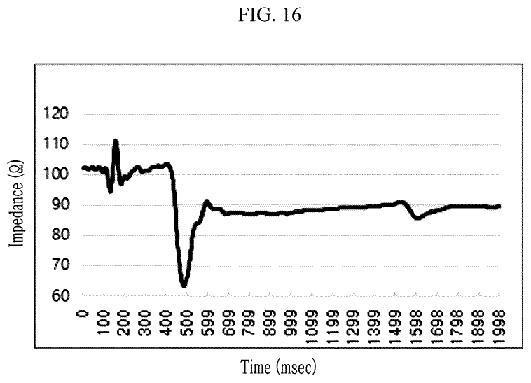

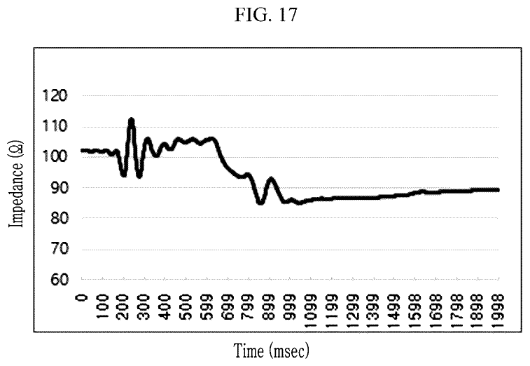

Referring to FIG. 16 and FIG. 17, an experimental example will be described. FIG. 16 and FIG. 17 are graphs that show a result of the experimental example.

In the present experimental example, for a first case where the plurality of insulation patterns ISP are not included between the circuit board PS and the connection portion CT and for a second case where the plurality of insulation patterns ISP are included between the circuit board PS and the connection portion CT like the other embodiments described herein, an electric signal is applied to one of the plurality of signal transmission lines STL of the circuit board PS and an impedance value over time is measured, and results are illustrated in FIG. 16 and FIG. 17. FIG. 16 is a graph illustrating the first case, and FIG. 17 is a graph illustrating the second case. For the first and second cases, all other conditions are the same except that whether or not the plurality of insulation pattern ISPs are included.

Referring to FIG. 16, it was confirmed that the impedance value changed significantly after about 500 msec after the electric signal was input. These changes in impedance values are caused due to unnecessary or undesired coupling with the connection portion.

Referring to FIG. 17, it was confirmed that the impedance value was not changed significantly after the electric signal was input and had a constant value after a certain period of time. In this way, in the second case where the plurality of insulation patterns ISP are included between the circuit board PS and the connection portion CT like the embodiments, it was confirmed that the impedance of the input electric signal was stably matched and maintained, and through this, it was confirmed that a stable electric signal could be supplied.

The display device according to embodiments may be applied to various electronic devices. An electronic device according to an embodiment may include the display device, and may further include modules or devices having additional functions other than the display device.

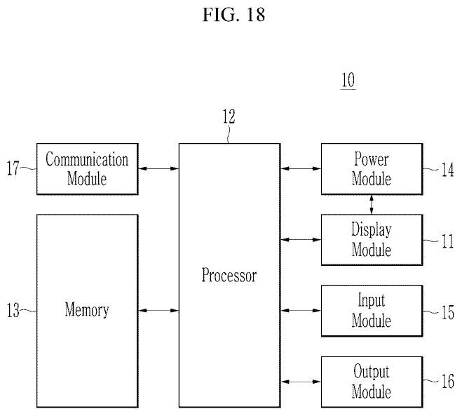

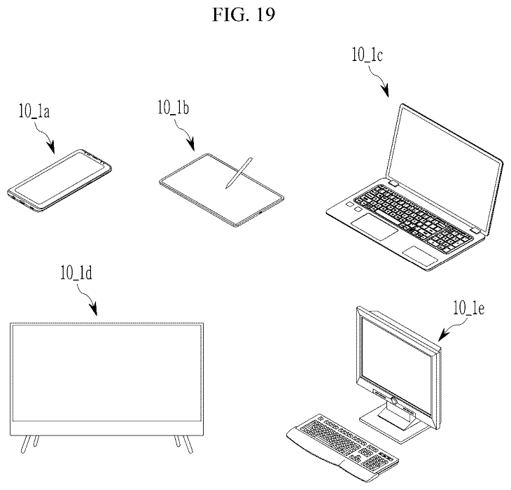

Referring to FIG. 18 to FIG. 21, an electronic device according to an embodiment will be described. FIG. 18 is a block diagram of an electronic device according to an embodiment, and FIGS. 19 to 21 are schematic views of electronic devices according to various embodiments.

Referring to FIG. 18, the electronic device 10 according to an embodiment may include a display module 11, a processor 12, a memory 13, and a power module 14. The electronic device 10 may further include an input module 14, a non-image output module 16, and/or a communication module 17.

The electronic device 10 may output various information in the form of images through the display module 11. In an example in which the processor 12 executes an application stored in the memory 13, image information provided by the application may be provided to a user through the display module 11. The power module 14 may include a power supply module such as, for example, a power adapter or a battery device, and a power conversion module that converts power supplied by the power supply module to generate power associated with operation of the electronic device 10. The input module 15 may provide input information to the processor 12 and/or the display module 11. The non-image output module 16 may receive non-image information from the processor 12, for example, sound, haptic, or light information, and provide the non-image information to the user. The communication module 17 is a module responsible for transmitting and receiving information between the electronic device 10 and external devices, and may include a receiver and a transmitter.

At least one of the components of the electronic device 10 described herein may be included in the display device according to the embodiments described herein. In some aspects, some of the individual modules that are functionally included in one module may be included in the display device, and other parts may be provided separately from the display device. For example, the display device may include the display module 11, and the processor 12, memory 13, and power module 14 may be provided in the form of other devices within the electronic device 10 that is not the display device.

FIGS. 19 to 21 illustrate examples of various electronic devices to which the display device according to the embodiments is applied.

FIG. 19 illustrates a smartphone 10_1a, a tablet personal computer (PC) 10_1b, a laptop 10_1c, a TV (television) 10_1d, and a desktop monitor 10_1e as examples of electronic devices.

The smartphone 10_1a may include an input module such as, for example, a touch sensor and a communication module in addition to the display module 11. The smartphone 10_1a may process information received through the communication module or other input modules to display information through the display module of the display device.

A tablet PC 10_1b, a laptop 10_1c, a TV 10_1d, and a desktop monitor 10_1e may include a display module and an input module similar to a smartphone 10_1a, and may further include a communication module in some cases.

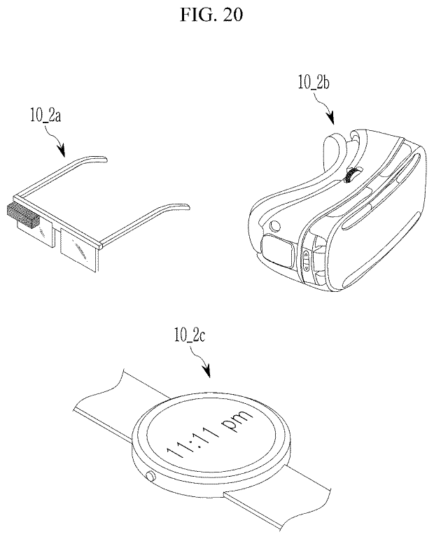

FIG. 20 illustrates an example case where an electronic device including a display module is applied to a wearable electronic device. The wearable electronic device may be smart glasses 10_2a, a head-mounted display 10_2b, a smart watch 10_2c, or the like.

The smart glasses 10_2a and the head-mounted display 10_2b may include a display module that emits display images and a reflector that reflects the emitted display screen to provide the images to the user's eyes, and through this, may provide virtual reality or augmented reality screens to the user.

The smart watch 10_2c includes a biosensor as an input device, and can provide biometric information recognized through the biosensor to the user through the display module.

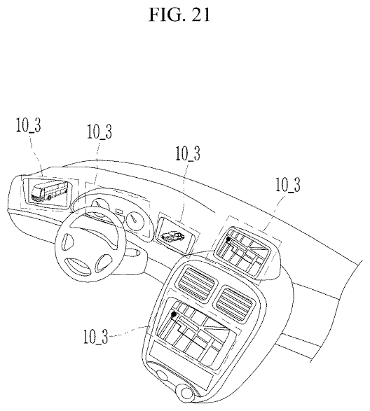

FIG. 21 illustrates an example case where an electronic device including a display module is applied to a vehicle. For example, the electronic device 10_3 may be applied to a vehicle instrument panel, a center fascia, or may be applied to a CID (Center Information Display) placed on a vehicle dashboard or a room mirror display replacing a side mirror.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

What is claimed is:

1. A drive portion for a display device, comprising:
a circuit board comprising a signal transmission line;
a connection portion attached to the circuit board; and
a plurality of insulation patterns located in an area where the circuit board and the connection portion overlap each other,
wherein the plurality of insulation patterns are located between the circuit board and the connection portion and do not overlap the signal transmission line.

2. The drive portion for the display device of claim 1, wherein an insulation resistance value of each of the plurality of insulation patterns ranges from about 1.00×10¹³ (Ω) to about 2.00×10¹³ (Ω).

3. The drive portion for the display device of claim 2, wherein the insulation resistance value of each of the plurality of insulation patterns ranges from about 1.30×10¹³ (Ω²) to about 1.60×10¹³ (Ω).

4. The drive portion for the display device of claim 1, wherein each of the plurality of insulation patterns comprises silk.

5. The drive portion for the display device of claim 1, wherein:
the connection portion overlaps the signal transmission line, and
the plurality of insulation patterns are located at a side of the signal transmission line.

6. The drive portion for the display device of claim 5, wherein the signal transmission line is a power transmission line.

7. The drive portion for the display device of claim 5, wherein:
the connection portion comprises a plurality of connection pins and a connection plate,
one or more of the plurality of connection pins are connected with the signal transmission line,
the connection plate is connected with the circuit board through expansion portions of opposite ends of the connection plate, and
the connection plate overlaps the signal transmission line and the plurality of insulation patterns.

8. The drive portion for the display device of claim 7, wherein the plurality of insulation patterns comprise:
a first insulation pattern overlapping the expansion portions of the connection plate; and
a second insulation pattern located at the side of the signal transmission line,
wherein a portion of the first insulation pattern extends along an edge of the connection plate,
wherein the first insulation pattern comprises a plurality of sub-insulation patterns arranged in a row and spaced apart from each other along a direction in which the connection plate extends, and
wherein:
the first insulation pattern comprises a plurality of sub-insulation patterns arranged in a row while being spaced apart from each other along a direction in which the connection plate extends, and
the plurality of sub-insulation patterns are arranged such that each of the plurality of sub-insulation patterns is diagonal with respect to with the direction in which the connection plate extends.

9. A display device comprising:
a display panel comprising a plurality of pixels;
a flexible circuit film connected to the display panel;
a circuit board connected to the flexible circuit film and comprising a signal transmission line;
a connection portion attached to the circuit board and connecting the flexible circuit film and the circuit board; and
a plurality of insulation patterns in an area where the circuit board and the connection portion overlap each other,
wherein the plurality of insulation patterns are located between the circuit board and the connection portion and do not overlap the signal transmission line.

10. The display device of claim 9, wherein an insulation resistance value of each of the plurality of insulation patterns ranges from about 1.30×10¹³ (Ω) to about 1.60×10¹³ (Ω).

11. The display device of claim 9, wherein each of the plurality of insulation patterns comprises silk.

12. The display device of claim 11, wherein:
the connection portion overlaps the signal transmission line, and
the plurality of insulation patterns are located at a side of the signal transmission line.

13. The display device of claim 12, wherein the signal transmission line is a power transmission line.

14. The display device of claim 12, wherein:
the connection portion comprises a plurality of connection pins and a connection plate,
one or more of the plurality of connection pins are connected with the signal transmission line,
the connection plate is connected with the circuit board through an expansion portion, and
the connection plate overlaps the signal transmission line and the plurality of insulation patterns.

15. The display device of claim 14, wherein the plurality of insulation patterns comprise:
a first insulation pattern overlapping the expansion portions of the connection plate; and
a second insulation pattern located at a surface of the signal transmission line.

16. The display device of claim 15, wherein a portion of the first insulation pattern extends along an edge of the connection plate.

17. The display device of claim 15, wherein the first insulation pattern comprises a plurality of sub-insulation patterns arranged in a row and spaced apart from each other along a direction in which the connection plate extends.

18. An electronic device comprising:
a display module comprising a display device; and
a processor connected to the display module and configured to control the display module to display an image,
wherein the display device comprises:
a display panel comprising a plurality of pixels;
a flexible circuit film connected to the display panel;
a circuit board connected to the flexible circuit film and comprising a signal transmission line;
a connection portion attached to the circuit board and connecting the flexible circuit film and the circuit board; and
a plurality of insulation patterns in an area where the circuit board and the connection portion overlap each other,
wherein the plurality of insulation patterns are located between the circuit board and the connection portion and do not overlap the signal transmission line.

19. The electronic device of claim 18, wherein an insulation resistance value of each of the plurality of insulation patterns ranges from about 1.30×10¹³ (Ω) to about 1.60×10¹³ (Ω).

20. The electronic device of claim 18, wherein each of the plurality of insulation patterns comprises silk.
